(19) United States
(12) Patent Application Publication
(10) Pub. No.: US 2026/0026365 A1
(43) Pub. Date: Jan. 22, 2026

(54) PACKAGED LATERAL POWER ELECTRONIC DEVICE AND A METHOD THEREOF

(71) Applicant: GaNPower International Inc., Vancouver (CA)

(72) Inventors: Zhanming LI, West Vancouver (CA); XiaoLi JI, Burnaby (CA)

(21) Appl. No.: 19/270,788

(22) Filed: Jul. 16, 2025

Related U.S. Application Data
(60) Provisional application No. 63/672,567, filed on Jul. 17, 2024.

(51) Int. Cl. H01L 23/495; H01L 23/00; H01L 23/14; H10D 30/47

(52) U.S. Cl. CPC H01L 23/49586; H01L 23/147; H01L 23/49582; H01L 24/32; H01L 2224/32245; H01L 2924/301; H10D 30/471

(57) ABSTRACT

A packaged lateral semiconductor device includes a resistor connected between the device substrate and a package ground point. The packaged device avoids the drawbacks of a floating substrate, and reduces substrate leakage current and increases breakdown voltage relative to conventionally packaged structures. Moreover, device substrate leakage current and breakdown voltage may be controlled by selecting a value of the resistor. Exemplary devices include high voltage lateral devices such as high-electron mobility transistors (HEMTs), implemented in technologies such as GaN or GaAs, where the packaging achieves high breakdown voltage with improved dynamic behavior.

### RELATED APPLICATION

This application claims the benefit of the filing date of U.S. Application No. 63/672,567 filed on Jul. 17, 2024, the contents of which are incorporated herein by reference in their entirety.

### FIELD

This disclosure relates to a field of power electronic devices, and in particular to packaging of lateral power electronic devices and a method for preparing the same.

### BACKGROUND

Gallium nitride (GaN) power high electron mobility transistors (HEMTs) are promising power devices due to their ability to achieve operation at high voltage, high frequency, high efficiency, and high power density, and as a result they are replacing previously popular devices based on silicon and silicon carbide. Currently, GaN power HEMTs are preferentially grown on silicon substrates for good performance with low cost.

One critical parameter for GaN HEMTs is breakdown voltage, which is subject to lateral breakdown (typically between drain and gate) or vertical breakdown through the vertical stack of the layered device.

For vertical breakdown, increasing the resistance of the vertical stack, including III-Nitrites and the substrate, can be helpful to suppress current leakage and improve the breakdown voltage. High-resistivity (HR) GaN fabricated by carbon or iron doping technologies is typically 10⁸˜10¹¹ ohm*cm, and it is difficult to increase further due to the resulting degraded material quality. If the high-resistivity GaN (HR—GaN) layer is not thick or resistive enough to sustain high voltage (e.g., >1000 V in the vertical direction, typically from drain to substrate), vertical leakage can occur, since the underlying silicon substrate has low resistivity and cannot block high voltage, resulting in current leakage into the substrate.

To reduce substrate leakage, electrically insulating and thermally conductive adhesive inserted between the silicon substrate and the device metal back plate has been suggested [1]. Analogously, an insulating substrate such as sapphire can also reduce substrate leakage. These approaches can effectively mitigate substrate leakage. However, insulating glue or insulating substrate will lead to a floating substrate with unsteady substrate voltage. This results in a back-gating effect and electron trapping phenomenon, and hence a poor dynamic behavior with an increased transient on-resistance during pulse operation, especially after high-drain voltage stress and when operated at high frequency. To eliminate the floating substrate, a semi-insulating and thermally conductive glue was suggested to replace electrically insulating glue [2]. However, the resistivity of semi-insulating glue is difficult to control to ensure consistent high yield and steady dynamic behavior.

### SUMMARY

According to one aspect of the invention, there is provided a packaged lateral semiconductor device, comprising: a semiconductor device package; a lateral semiconductor device die mounted to a metal backboard of the package with one or more intervening layers, the lateral semiconductor device die comprising: at least one semiconductor layer, the at least one semiconductor layer comprising first and second substantially opposed surfaces; source, gate, and drain electrodes disposed on the first surface of the at least one semiconductor layer; and an electrically conducting material in electrical contact with the second surface of the at least one semiconductor layer; the packaged device further comprising a resistor connected between the electrically conducting material and an electrical ground point of the package.

According to another aspect of the invention, there is provided a method for preparing a packaged lateral semiconductor device, comprising: mounting a lateral semiconductor device die to a metal backboard of a semiconductor die package with one or more intervening layers, the lateral semiconductor device die comprising: at least one semiconductor layer, the at least one semiconductor layer comprising first and second substantially opposed surfaces; source, gate, and drain electrodes disposed on the first surface of the at least one semiconductor layer; and an electrically conducting material in electrical contact with the second surface of the at least one semiconductor layer; and connecting a resistor between the electrically conducting material and an electrical ground point of the package.

In some embodiments, the electrically conducting material in electrical contact with the second surface of the at least one semiconductor layer comprises an electrically conductive substrate.

In some embodiments, the packaged lateral semiconductor device includes an insulating substrate; wherein the electrically conducting material in electrical contact with the second surface of the at least one semiconductor layer is disposed between the second surface of the at least one semiconductor layer and the insulating substrate.

In some embodiments, the lateral semiconductor device is selected from a high electron mobility transistor (HEMT) and a metallic oxide semiconductor field effect transistor (MOSFET).

In some embodiments, the lateral semiconductor device may be implemented in a semiconductor technology selected from GaN, GaAs, and InP.

In some embodiments, the resistor may have a value in the range of about 1 MΩ to about 200 MΩ.

In some embodiments, the electrically conductive substrate may comprise a material selected from Si, SiC, GaN, GaAs, and InP.

In some embodiments, the insulating substrate may comprise a material selected from sapphire and Ga₂O₃.

In some embodiments, the package may be selected from a lead-frame package and a flip-chip package.

Embodiments address the limitations of prior approaches by providing new packaging structures and related methods.

In some embodiments, this invention provides a packaged gallium-based (e.g., GaN) power device comprising a resistor connected between the device substrate and ground. Embodiments avoid substrate floating, and hence mitigate back-gating and electron trapping effects and their negative impacts on the device's dynamic behavior. Also, embodiments suppress the substrate leakage current by inserting the resistor and therefore improve breakdown voltage. Embodiments may be applied to lateral high voltage GaN and GaAs HEMT device packaging to achieve high breakdown voltage with good dynamic behavior. Methods of manufacturing packaged gallium-based (e.g., GaN) power devices by connecting device substrate to ground via an external resistor are also provided.

Another aspect of the disclosure provides a method for packaging a GaN power device which is grown on a weakly conductive Si substrate.

Another aspect of the disclosure provides a method for packaging a GaN power device which is grown on an insulating substrate. In one embodiment, a conductive layer is deposited before an epitaxial HR GaN layer.

Another aspect of the disclosure includes packaged devices with insulating substrates, for example, sapphire or Ga₂O₃.

Embodiments include flip-chip packaging on an insulating substrate.

### BRIEF DESCRIPTION OF THE DRAWINGS

For a better understanding of the invention, and to show more clearly how it may be carried into effect, embodiments will be described, by way of example, with reference to the accompanying drawings, wherein:

FIGS. 1A and 1B are diagrams of GaN HEMT structures according to the prior art, wherein FIG. 1A shows a floating substrate and FIG. 1B shows a grounded substrate.

FIGS. 2A and 2B are plots showing results of simulations of a floating substrate GaN HEMT according to the prior art, wherein FIG. 2A shows potential distribution with Vd=700 V, Vg=Vs=0 V, and FIG. 2B shows drain current as a function of substrate voltage.

FIG. 3 is a circuit diagram of a GaN HEMT according to one embodiment of the invention.

FIGS. 4A and 4B are plots showing results of simulations of GaN HEMTS according to embodiments with the substrate connected to an external resistor of 100Ω, 100 kΩ, 1 MΩ, and 10 MΩ, wherein FIG. 4A is substrate leakage current vs drain voltage and FIG. 4B is substrate voltage vs drain voltage.

FIG. 5 is a diagram showing a side view of a structure of a packaged GaN HEMT power device on a conductive substrate, according to one embodiment.

FIG. 6 is a diagram showing a side view of a structure of a packaged GaN HEMT power device on an insulating substrate, according to one embodiment.

FIG. 7 is a diagram showing a side view of a structure of a flip-chip packaged GaN HEMT power device on an insulating substrate, according to one embodiment

### DETAILED DESCRIPTION OF EMBODIMENTS

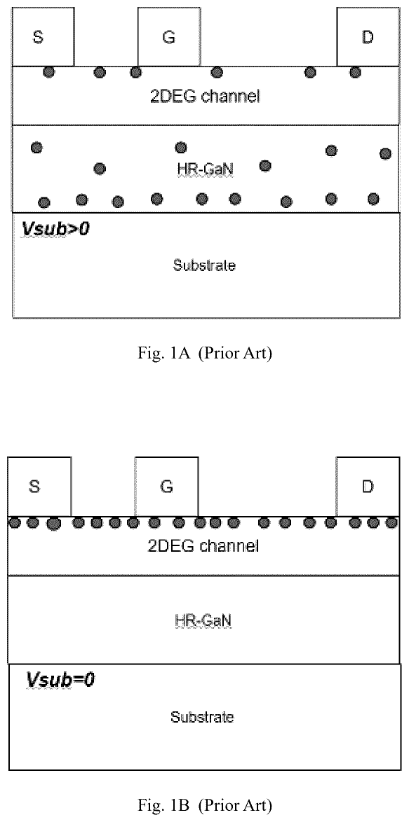

FIGS. 1A and 1B are diagrams of a GaN HEMT structure according to the prior art, wherein the dark circles represent electrons. The HEMT structures include source S, gate G, and drain D electrodes on a 2-dimensional electron gas (2-DEG) layer, a high-resistivity (HR) GaN buffer layer, and the substrate. FIG. 1A shows a floating substrate induced back-gating and electron trapping effect, and FIG. 1B shows a grounded substrate. For a floating substrate, after off-state drain voltage stress, a positive voltage appears at the substrate/GaN interface, which acts like a back gate and results in electron trapping in the HR-GaN buffer layer. When the device is turned on, the trapped electrons cannot recover immediately and result in current collapse and degradation of dynamic on-resistance.

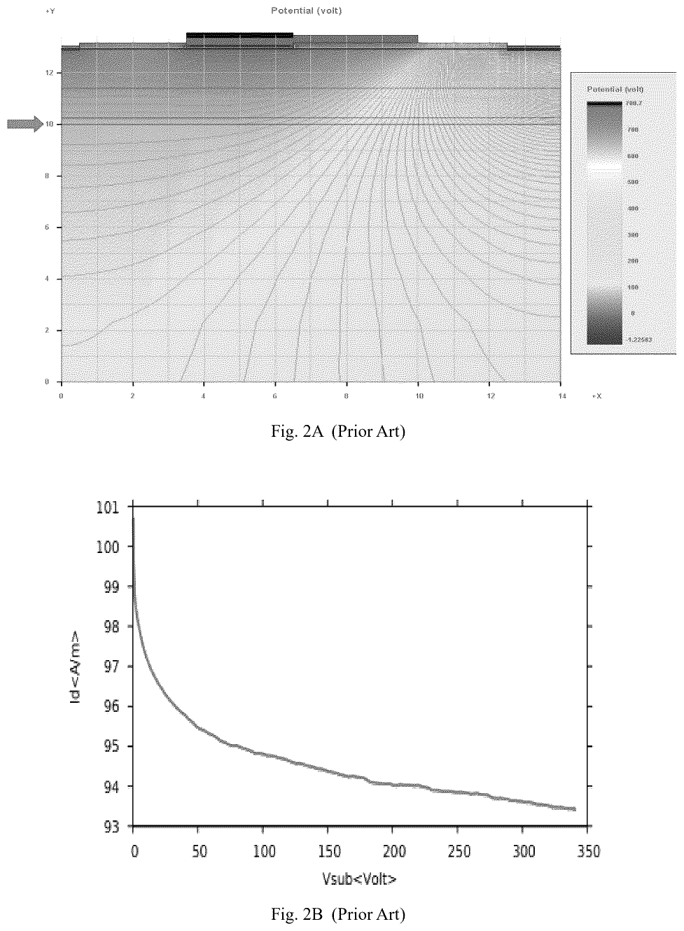

A simulation was performed using APSYS™ (Crosslight Software Inc.) to investigate potential (i.e., voltage) effects in a conventionally packaged floating substrate GaN HEMT in the off-state. The results are shown in FIGS. 2A and 2B. FIG. 2A is a plot showing the potential distribution with the source at the left side of the plot and the drain at the right side of the plot, where the arrow at the left shows the GaN/substrate interface. The interface voltage is very high and it also rises from source side (left) to drain side (right). This result demonstrates that a floating substrate can lead to a high substrate voltage in the off-state. FIG. 2B shows the simulation result for the effect of floating substrate voltage on drain current, where the drain current as a function of substrate bias was simulated. The result shows that the drain current decreases as substrate bias increases, which can be attributed to the electron trapping effect as described above.

According to one aspect, the invention provides packaged lateral semiconductor switching devices, and methods therefor, with reduced substrate leakage current and increased breakdown voltage relative to conventionally packaged structures.

As used herein, the term “lateral” semiconductor switching device refers to a transistor where the current flow is primarily parallel to the surface of the semiconductor material, unlike vertical devices where current flows perpendicular to the surface.

As described herein, embodiments include a resistive element connected between the device substrate and an electrical grounding point. By incorporating a resistive element, a floating substrate is avoided, which mitigates back-gating and electron trapping effects and their negative impacts on the device's dynamic behavior. Also, by incorporating a resistive element substrate leakage current is reduced, which improves (raises) breakdown voltage.

Approaches and methods described herein are applicable to lateral semiconductor devices and their uses where substrate leakage is a problem that negatively affects device dynamic (e.g., switching) behavior and circuit performance. Such lateral devices may include, but are not limited to, e.g., transistors such as lateral field effect transistors (FETs), e.g., HEMTs, MOSFETs, etc., implemented in a gallium-based semiconductor material such as, e.g., gallium nitride (GaN), gallium arsenide (GaAs), etc., or other semiconductor materials such as indium phosphide (InP). Although embodiments are described herein primarily with respect to GaN, it will be appreciated that embodiments may be readily applied and/or adapted to, e.g., GaAs and InP due to the similarities in their layered structures and in the substrates used.

As described herein, packaged structures may include at least one lateral semiconductor device die together with at least one resistive element. In some embodiments the resistive element may be external to the lateral device die, which may be referred to herein as an external resistor. An external resistor may be implemented using, e.g., a surface mount device (SMD) resistor, a film resistor, a wire resistor, etc. In some embodiments the resistive element may be integrated with the lateral device die, which may be implemented by doping a semiconductor material, ion-implanting a semiconductor material, back-to-back PN junctions, etc. Advantageously, an integrated resistive element may be implemented during device die fabrication which may reduce the number of processing steps of the packaged device. The package may be, for example, a lead-frame package, a flip-chip package, etc.

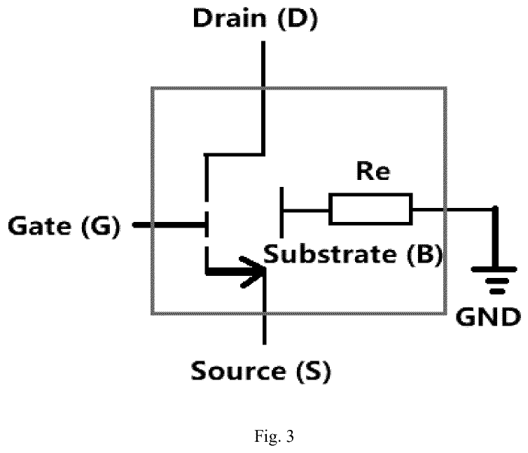

FIG. 3 is a circuit diagram of a generalized embodiment based on a HEMT. Referring to FIG. 3, the HEMT has gate G, drain D, and source S terminals, and the HEMT is fabricated on a substrate B. A resistive element, which in some embodiments may be, e.g., an external resistor Re, is connected between the HEMT substrate B and electrical grounding point of the packaged device. In other embodiments the resistive element may be integrated with the device die. The resistor value may be selected to achieve a desired substrate leakage current and breakdown voltage, and may be, for example, from about 1 MΩ to about 200 MΩ. The resistive element may also be referred to herein simply as a resistor.

The value of the resistive element may be selected by simulation, calculation, or by prototyping, testing, etc. For example, a leakage current of 1 μA at 1200 V may be selected for a given device application. A simulation of the leakage current versus external resistor value may be conducted (e.g., using APSYS, Sentaurus™ (Synopsys, Inc.), or products available from Silvaco Group, Inc., etc., to determine the necessary resistance value to meet the leakage current limit at breakdown voltage and to confirm that the maximum electrical field in the buffer layer does not exceed its typical limit. The inventors have found that a value of about 1 MΩ or larger sufficiently suppresses the leakage current in most applications. The resistor will withstand high voltage and its power dissipation will be <V_{br}²/R, where V_{br} is the breakdown voltage. Further, because the resistance value can be accurately controlled during fabrication and/or packaging of the HEMT, there is a high degree of consistency among devices, resulting in high yield with consistent device performance characteristics.

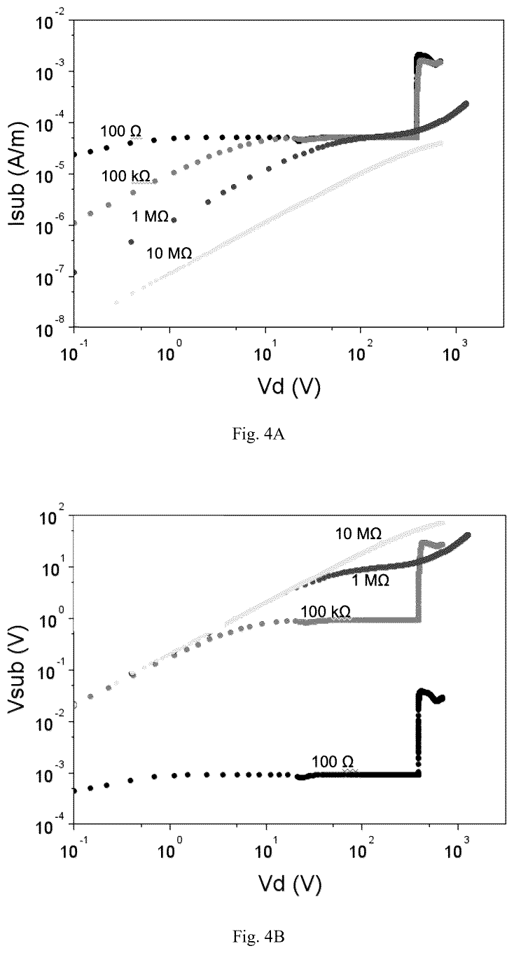

Simulations were performed using APSYS to investigate the effect of different resistive element (e.g., resistor Re) values on substrate leakage current and substrate voltage. The results are shown in FIG. 4A, which is a plot of substrate leakage current vs drain voltage, and in FIG. 4B, which is a plot of substrate voltage vs drain voltage. As shown in FIG. 4A, the substrate leakage current decreases as the resistance value increases from 100Ω to 10 MΩ. Thus, a large resistor, e.g., about 1 MΩ or larger, can effectively reduce the substrate leakage current. However, as shown in FIG. 4B, increasing the resistance value also leads to a higher substrate voltage. In general, using a resistive element according to embodiments described herein effectively suppresses the substrate leakage, resulting in a moderate substrate leakage current and a substrate voltage between that of a grounded substrate and floating substrate. This represents a trade-off between breakdown voltage and dynamic behavior. Moreover, because the resistance value of the resistive element may be selected for a desired substrate leakage current and substrate breakdown voltage (V_{br}), the trade-off may be designed and optimized for a given HEMT device and/or circuit application, e.g., for optimal steady dynamic behavior.

Embodiments may be implemented on conductive or semi-insulating substrates, such as, but not limited to, silicon, silicon carbide (SiC), GaN, GaAs, or InP, or insulating substrates, such as, but not limited to, sapphire or gallium (III) oxide (Ga₂O₃) substrates.

Non-limiting examples according to various embodiments are described below.

### EXAMPLE 1

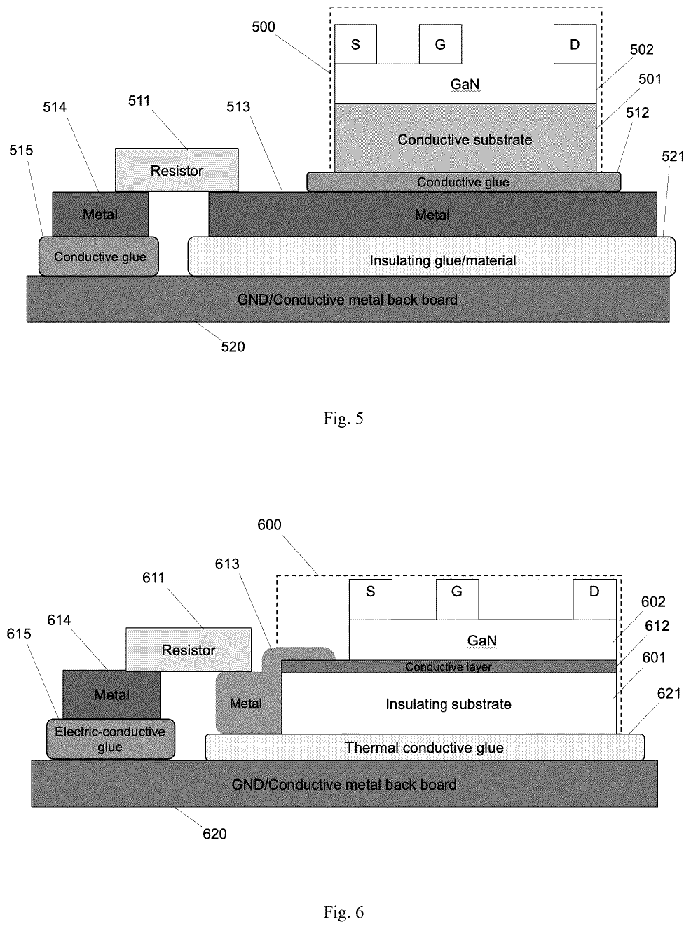

This example describes a structure of a packaged GaN lateral power device according to an embodiment implemented on a conductive substrate, with reference to the diagram of FIG. 5. It is readily apparent that the structure of a packaged GaAs or InP lateral power device implemented on a conductive substrate is similar.

Referring to FIG. 5, a GaN HEMT die 500 includes source S, gate G, and drain D terminals on a surface of a GaN layer 502, and a conductive substrate 501. The GaN layer 502 includes various GaN-based epitaxial layers, such as, e.g., GaN, AlN, AlGaN/Sls buffer, HR-GaN, 2-DEG channel, and p-GaN if applicable. A conductive glue 512 adheres the conductive substrate 501 to a first metal backplate 513 which may be, e.g., aluminum (Al). An insulating (i.e., non-electrically conducting) glue or other material 521 adheres the metal backplate to a conductive metal backboard 520 (e.g., a backboard of the package). The metal backboard 520 may be connected to a ground point of a circuit when the packaged device is used in the circuit. As shown in FIG. 5, a resistor 511 is connected between the first metal backplate 513 and a second metal backplate 514, which may be, e.g., aluminum. The second metal backplate 514 is adhered to the metal backboard 520 using a conductive glue 515. It will be appreciated that the embodiment of FIG. 5 implements a packaged GaN HEMT on a conductive substrate including a resistor 511 that provides a path for current flow from the HEMT substrate 501 to circuit ground. By selecting a desired resistance value of the resistor 511, the current flow to ground can be controlled.

### EXAMPLE 2

This example describes a structure of a packaged GaN lateral power device according to an embodiment implemented on an insulating substrate, with reference to the diagram of FIG. 6. It is readily apparent that the structure of a packaged GaAs or InP lateral power device implemented on an insulating substrate is similar.

Referring to FIG. 6, a GaN HEMT die 600 includes source S, gate G, and drain D terminals on a surface of a GaN layer 602, a first conductive layer 612 such as a metal (e.g., aluminum), and an insulating substrate 601 (e.g., sapphire, Ga₂O₃). The GaN layer 602 includes various GaN-based epitaxial layers, such as, e.g., GaN, AlN, AlGaN/Sls buffer, HR-GaN, 2-DEG channel, and p-GaN if applicable. A thermally conductive glue 621 adheres the insulating substrate 601 to a conductive metal backboard 620 (e.g., a backboard of the package). The metal backboard 620 may be connected to a ground point of a circuit when the packaged device is used in the circuit. As shown in FIG. 6, a first metal 613 is disposed in contact with the first conductive layer 612, and a resistor 611 is connected between the first metal 613 and a second metal 614, which may be, e.g., aluminum. The second metal 614 may be adhered to the metal backboard 620 using a conductive glue 615. It will be appreciated that the embodiment of FIG. 6 implements a packaged GaN HEMT on an insulating substrate including a resistor 611 that provides a path for current flow from the HEMT conductive layer 612 to circuit ground. By selecting a desired resistance value of the resistor 611, the current flow to ground can be controlled.

### EXAMPLE 3

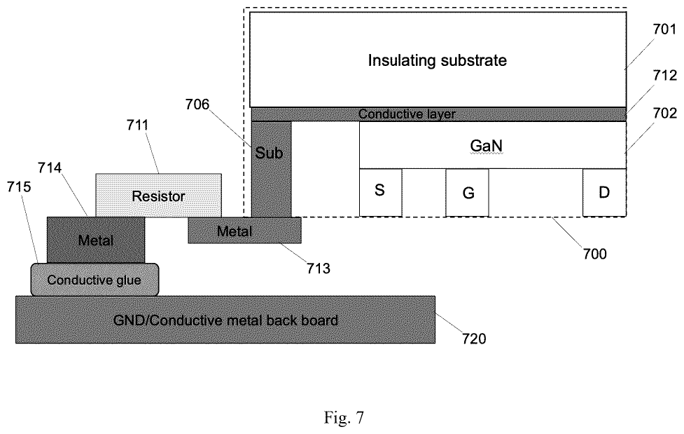

This example describes a structure of a flip-chip packaged GaN lateral power device according to an embodiment implemented on an insulating substrate, with reference to the diagram of FIG. 7. It is readily apparent that the structure of a flip-chip packaged GaAs or InP lateral power device implemented on an insulating substrate is similar.

Referring to FIG. 7, a GaN HEMT die 700 includes source S, gate G, and drain D terminals on a surface of a GaN layer 702, a first conductive layer 712 such as a metal (e.g., aluminum), and an insulating substrate 701 (e.g., sapphire, Ga₂O₃). The GaN layer 702 includes various GaN-based epitaxial layers, such as, e.g., GaN, AlN, AlGaN/Sls buffer, HR—GaN, 2-DEG channel, and p-GaN if applicable. As shown in FIG. 7, a conductive material 706 such as a metal is disposed as a substrate electrode in contact with the first conductive layer 712, and a first metal 713 is disposed in contact with the conductive material 706. A resistor 711 is connected between the first metal 713 and a second metal 714, which may be, e.g., aluminum. The second metal 714 may be adhered to a conductive metal backboard 720 (e.g., a backboard of the package) using a conductive glue 715. The metal backboard 720 may be connected to a ground point of a circuit when the packaged device is used in the circuit. It will be appreciated that the embodiment of FIG. 7 implements a flip-chip packaged GaN HEMT on an insulating substrate including a resistor 711 that provides a path for current flow from the HEMT conductive layer 712 to circuit ground. By selecting a desired resistance value of the resistor 711, the current flow to ground can be controlled.

All cited publications are incorporated herein by reference in their entirety.

### EQUIVALENTS

While the invention has been described with respect to illustrative embodiments thereof, it will be understood that various changes may be made to the embodiments without departing from the spirit and scope of the invention. Accordingly, the described embodiments are to be considered exemplary and the invention is not to be limited thereby.

### REFERENCES

[1] U.S. Pat. No. 11,107,755 B2 issued Aug. 31.2021
[2] U.S. Patent Application Publication No. 2024/0021677

1. A packaged lateral semiconductor device, comprising:
a semiconductor device package;
a lateral semiconductor device die mounted to a metal backboard of the package with one or more intervening layers, the lateral semiconductor device die comprising:
at least one semiconductor layer, the at least one semiconductor layer comprising first and second substantially opposed surfaces;
source, gate, and drain electrodes disposed on the first surface of the at least one semiconductor layer;
an electrically conducting material in electrical contact with the second surface of the at least one semiconductor layer;
a resistor connected between the electrically conducting material and an electrical ground point of the package.

2. The packaged lateral semiconductor device of claim 1, wherein the electrically conducting material in electrical contact with the second surface of the at least one semiconductor layer comprises an electrically conductive substrate.

3. The packaged lateral semiconductor device of claim 1, further comprising an insulating substrate;
wherein the electrically conducting material in electrical contact with the second surface of the at least one semiconductor layer is disposed between the second surface of the at least one semiconductor layer and the insulating substrate.

4. The packaged lateral semiconductor device of claim 1, wherein the lateral semiconductor device is selected from a high electron mobility transistor (HEMT) and a metallic oxide semiconductor field effect transistor (MOSFET).

5. The packaged lateral semiconductor device of claim 1, wherein the lateral semiconductor device is implemented in a semiconductor technology selected from GaN, GaAs, and InP.

6. The packaged lateral semiconductor device of claim 1, wherein the resistor has a value in the range of about 1 MΩ to about 200 MΩ.

7. The packaged lateral semiconductor device of claim 2, wherein the electrically conductive substrate comprises a material selected from Si, SiC, GaN, GaAs, and InP.

8. The packaged lateral semiconductor device of claim 3, wherein the insulating substrate comprises a material selected from sapphire and Ga₂O₃.

9. The packaged lateral semiconductor device of claim 1, wherein the package is selected from a lead-frame package and a flip-chip package.

10. A method for preparing a packaged lateral semiconductor device, comprising:
mounting a lateral semiconductor device die to a metal backboard of a semiconductor die package with one or more intervening layers, the lateral semiconductor device die comprising:
at least one semiconductor layer, the at least one semiconductor layer comprising first and second substantially opposed surfaces;
source, gate, and drain electrodes disposed on the first surface of the at least one semiconductor layer;
an electrically conducting material in electrical contact with the second surface of the at least one semiconductor layer;
connecting a resistor between the electrically conducting material and an electrical ground point of the package.

11. The method of claim 10, wherein the electrically conducting material in electrical contact with the second surface of the at least one semiconductor layer comprises an electrically conductive substrate.

12. The method of claim 10, wherein the lateral semiconductor device further comprises an insulating substrate;
wherein the electrically conducting material in electrical contact with the second surface of the at least one semiconductor layer is disposed between the second surface of the at least one semiconductor layer and the insulating substrate.

13. The method of claim 10, wherein the lateral semiconductor device is selected from a high electron mobility transistor (HEMT) and a metallic oxide semiconductor field effect transistor (MOSFET).

14. The method of claim 10, wherein the lateral semiconductor device is implemented in a semiconductor technology selected from GaN, GaAs, and InP.

15. The method of claim 10, wherein the resistor has a value in the range of about 1 MΩ to about 200 Ω.

16. The method of claim 11, wherein the electrically conductive substrate comprises a material selected from Si, SiC, GaN, GaAs, and InP.

17. The method of claim 12, wherein the insulating substrate comprises a material selected from sapphire and Ga₂O₃.

18. The method of claim 10, wherein the package is selected from a lead-frame package and a flip-chip package.
